(19) United States
(12) Patent Application Publication
(10) Pub. No.: US 2022/0255471 A1
(43) Pub. Date: Aug. 11, 2022

(54) An Energy Harvesting System, Fastener, Use, and Method for the Conversion of Kinetic Energy into Electrical Energy

(71) Applicant: SENS-IN S.r.l., San Lazzaro Di Savena (IT)

(72) Inventors: Simone Ravaglia, San Lazzaro Di Savena (IT); Mattia Paganelli, San Lazzaro Di Savena (IT)

(73) Assignee: SENS-IN S.r.l., San Lazzaro Di Savena (IT)

(21) Appl. No.: 17/629,240

(22) PCT Filed: Jul. 22, 2020
(86) PCT No.: PCT/IB2020/056904

§ 371 Date: Jan. 21, 2022

(30) Foreign Application Priority Data
Jul. 22, 2019 (IT) 102019000012564

(51) Int. Cl. H02N 2/18; H01L 41/113; H01L 41/047; H01L 41/053

(52) U.S. Cl. CPC H02N 2/186; H01L 41/053; H01L 41/047; H01L 41/113

(57) ABSTRACT

An energy harvesting system, fastener, use of an energy harvesting system and method for the conversion of kinetic energy into electrical energy are provided, the harvesting system being made, at least partially, of a piezoelectrical material, wherein the fastener is configured to guarantee the joining of a plurality of components of a mechanical apparatus, and the method comprising conversion of kinetic energy into electrical energy at each junction area having the disclosed fastener.

### CROSS-REFERENCE TO RELATED APPLICATIONS

This patent application claims priority from Italian patent application no. 102019000012564 filed on Jul. 22, 2019, the entire disclosure of which is incorporated herein by reference.

### TECHNICAL FIELD

The present invention relates to an energy harvesting system, a fastener, the use of an energy harvesting system and a method for the conversion of kinetic energy into electrical energy.

In particular, the present invention relates to an energy harvesting system capable of recovering energy from a kinetic source (for example, from vibrations).

Furthermore, the present invention relates to a fastener, in particular a screw, which comprises this type of energy harvesting system, so as to ensure, in addition to the function of joining the components of a mechanical apparatus, the function of converting kinetic energy into electrical energy and, if necessary, storing the latter.

### BACKGROUND ART

The use of fasteners is known, in particular screws, for connecting mechanical components to one another. During use, the fasteners, in particular the screws, are subjected to elevated mechanical stress and they must have elevated mechanical resistance (and often thermal resistance, too) so as to ensure the correct operation, over time, of the mechanical apparatus, in which they are applied.

The fasteners, in particular the screws, are applied in a great number of mechanical apparatuses. The fasteners, in particular the screws, are often installed in positions, which are subjected to elevated vibrations. For example, at a head of a combustion engine, or on aeronautical and aerospace vehicles.

In general, a fastener comprises a shank, which forms the main connection/seal element, depending on the type of tightening element the shank can have a head or it can cooperate with other components, such as: nuts, washers, or similar. Preferably, the fastener is configured to tighten bodies, which are subjected to elevated dynamic stress, i.e. vibrations, and/or thermal stress.

One example of a fastener is the tight screw, which comprises, in addition to the shank, a head, projecting both axially and radially outwards from the shank. In particular, a tight screw is used for tightening the head of a motor and it has a length, i.e. an extension along the longitudinal axis, which is significantly greater than the diameter thereof.

Special fasteners are also known, such as special tight screws, i.e. made of a high-performance material, which is lighter than steel (generally for automotive or aerospace applications)

Preferably, the present invention relates to tightening elements, in particular screws, made of a material with elevated mechanical and thermal resistance, for example, made of titanium alloy.

It is also known to provide sensors installed inside the fasteners; however, such sensors must be electrically powered, therefore, either a battery is provided inside the fastener or, generally, cables are used for connecting the sensors to an external power supply.

Clearly, the solution of the cables has the drawback of having to involve an external supply and, therefore, of being able to use this type of sensorised fasteners mainly in the bench test steps and/or in areas where the fastener is not moving or where it can be reached with a cable.

In other technical fields, the use of technologies that are capable of recovering/storing energy from environmental sources is also known. This includes solar, thermal, wind, and kinetic energy.

Energy harvesting systems are also known, which are capable of converting the kinetic energy into mechanical energy by means of using mechanical oscilloscopes. However, this type of energy harvesting/ conversion system relates to large mechanical apparatuses (for example, wind turbines or systems, which recover energy from wave motion).

Additionally, energy harvesting systems are known, to be applied to mobile devices, as described for example in US2015288299 A1.

Energy harvesting systems that can be applied to existing mechanical apparatuses, such as cars, planes, or aerospace vehicles, without having to modify the configurations and/or functionality of the same, are not known.

Energy harvesting systems that are configured to be applied inside a fastener, such as a screw, are not known. In other words, energy harvesting systems that are: capable of withstanding the stress to which a fastener is subjected in use; sufficiently miniaturised for ensuring adequate mechanical resistance of the fastener (without weakening it too much); and ensuring a significant electrical energy storage/harvesting (i.e. which justifies the use thereof in terms of cost/benefits), are not known.

### DISCLOSURE OF INVENTION

It is one purpose of the present invention to provide an energy harvesting system that can be used in mechanical components of limited dimensions, such as fasteners, and that can be subjected to elevated mechanical and thermal stress.

It is one purpose of the present invention to provide a fastener, in particular a screw or similar, capable of ensuring adequate mechanical resistance (for fulfilling the main purpose thereof of joining) and, at the same time, which is capable of recovering electrical energy, for reusing and/or storing, from kinetic phenomena, to which the fastener is subjected in use.

According to the present invention, an energy harvesting system is provided, as stated in the attached claims.

According to the present invention, a fastener is provided, as stated in the attached claims.

According to the present invention, the use of an energy harvesting system is provided, as stated in the attached claims.

According to the present invention, a method is provided for harvesting energy, as stated in the attached claims.

### BRIEF DESCRIPTION OF THE DRAWINGS

The present invention will now be described with reference to the attached drawings, illustrating a non-limiting embodiment thereof:

FIG. 1 is a partially sectional side view of a fastener according to the present invention;

FIG. 2 is a plan view of the fastener in FIG. 1;

FIG. 3 is a partially sectional side view of a variation of the fastener according to the present invention;

FIG. 4 is a schematic view of a harvesting system according to the present invention;

FIG. 5 is a perspective and schematic view of a variation of the harvesting system according to the present invention;

FIGS. 6 and 7 are a side view and a perspective view respectively, with parts removed for clarity, of a variation of a harvesting system according to the present invention;

FIGS. 8 and 9 are a side view and a perspective view respectively, with parts removed for clarity, of a variation of a harvesting system according to the present invention; and

FIGS. 10 and 11 are a side view and a perspective view respectively, with parts removed for clarity, of a variation of a harvesting system according to the present invention;

FIGS. 12 to 14 are examples of a detail of a harvesting system according to the present invention.

### BEST MODE FOR CARRYING OUT THE INVENTION

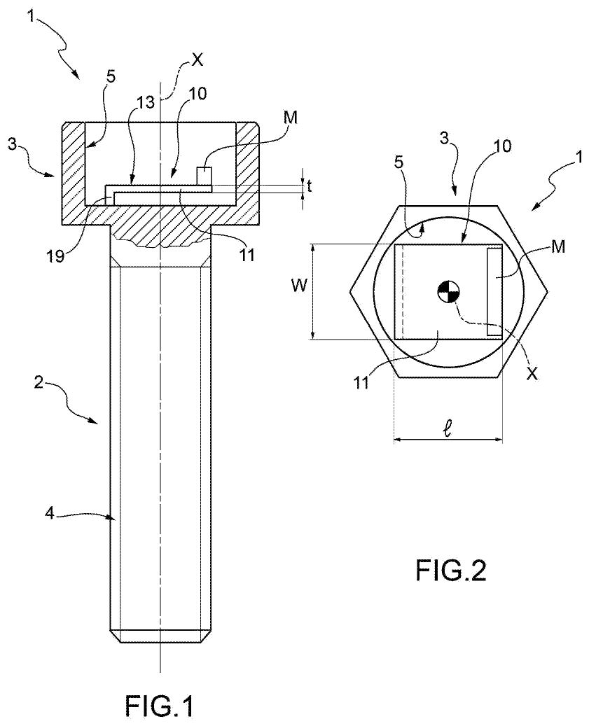

In FIG. 1, a fastener 1 according to the present invention is globally denoted with 1.

Advantageously, a fastener 1 is configured to connect two or more mechanical components to one another and to withstand elevated mechanical and thermal stress.

Without loss of generality, as mentioned previously, the technical solution concerns any type of fastener 1.

Advantageously, the fastener 1 is configured to withstand elevated temperatures, in particular temperatures greater than the melting point of steel, such as temperatures greater than 1300° C.

Advantageously, the fastener 1 is made of a material with high mechanical resistance.

Advantageously, the fastener 1 is made, at least partially, of a material selected from the following group of materials: titanium, titanium alloys; nickel-chrome alloys generally known as INCONEL®; stainless steel X1CrNiMoAlTi612-11-2 generally known as MLX17®; stainless steel X1NiCrMoAlTi12-10-2 generally known as MLX19®; and stainless steels class PH (Precipitation Hardening) ranging between 13-8 or 15-5 or 17-4; Steel with composition Si, 19.00-21.00 Cr, 33.00-37.00 Ni, 9.00-11.00 Mo, 1.00 max. Ti, 0.01 B, 1.00 max Fe, Bal Co generally known as MP35N®; steels comprising nickel and cobalt generally known as MARAGING® and/or VASCOMAX®, for example, MARAGING300 or AERMET®100; steels AISI4340, AFNOR30NiCrMo16 and stainless series AISI300 and series AISI400.

In FIG. 1, a screw 1, comprising a shank 2 and a head 3, is globally schematised as an example of a fastener 1. The screw 1 has a longitudinal rotation axis X and a threaded portion 4 made on the outer surface of the shank 2.

For example, the screw 1 can be a tight screw having a length greater than 150 or 200 mm, preferably about 300 mm.

According to a variation, which is not illustrated, the screw can be made up of a plurality of components, which are tightened and locked to one another, so as to form a single body. In other words, according to a variation, which is not illustrated, the fastener 1, in particular a screw 1 may not be a single monolithic piece. For example, the screw can comprise a shank and a nut tightened and locked to each other, so as to form a single body. As said previously, the fastener 1 according to the present invention can be different from the screw, for example, it can be a bolt, a rod, a stud, a rivet, or the like.

Advantageously, the fastener 1 comprises an energy harvesting system 10, which is configured to recover energy from kinetic phenomena, to which the fastener 1 is subjected in use.

According to the example in FIGS. 1 and 2, the screw has a housing 5 in the head 3 and the energy harvesting system 10 is inserted inside the head 3 of the screw.

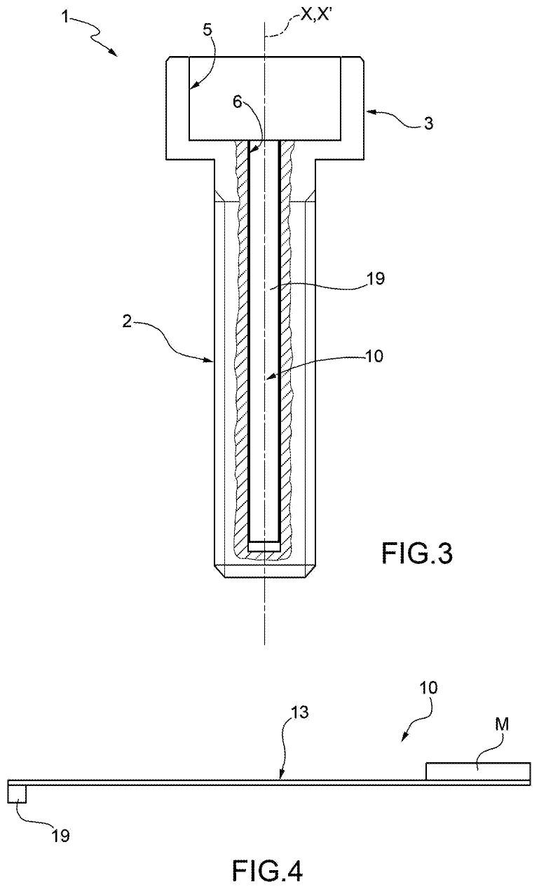

According to the variation shown in FIG. 3, the screw has a cavity, which extends along the shank 2 and the harvesting system 10 is inserted inside the shank 2.

Advantageously, the harvesting system 10 comprises a sensitive element 11, and a mass M.

The sensitive element 11 is configured to convert the kinetic energy, which hits it, into a potential difference. In other words, the sensitive element 11 is configured to convert the kinetic energy into electrical energy. Advantageously, the harvesting system 10 is of the piezoelectrical type.

Advantageously, the sensitive element 11 comprises at least a part made of a piezoelectrical material. A piezoelectrical material is known to generate a charge imbalance on the faces thereof when it is subjected to a force/is deformed. The sensitive element 11 comprises a piezoelectrical transducer 13.

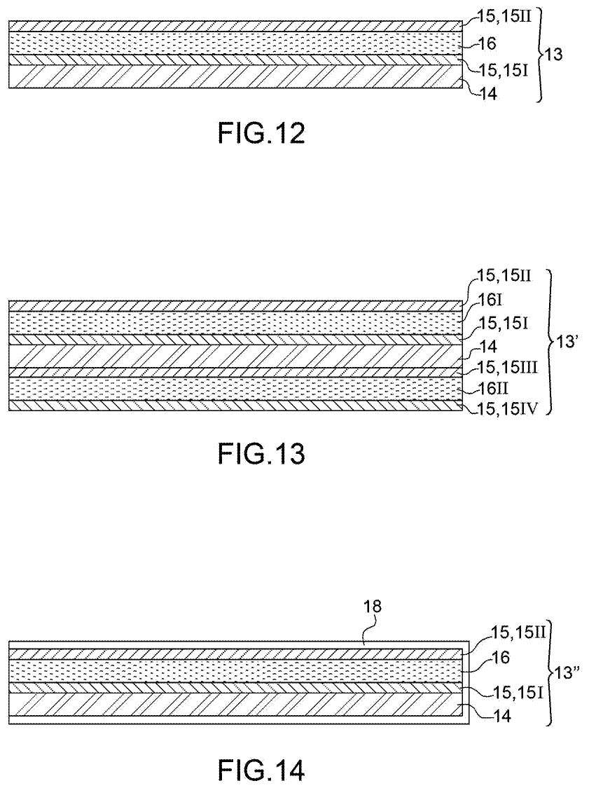

Sections of known structures of piezoelectrical transducers 13 are schematically illustrated in FIGS. 12 to 14.

A piezoelectrical transducer 13 generally comprises a wafer structure consisting, in order, of the following sequence of components:
a substrate 14;
an electrode 15I;
a piezoelectrical material layer 16;
an additional electrode 15II.

Advantageously, the substrate 14 is made of an elastic material in this way the piezoelectrical transducer 13, in turn, has a good elasticity.

Advantageously, the substrate 14 is made, at least partially, of: brass and/or carbon fibre and/or stainless steel and/or non-magnetic material, such as brass with silver.

The piezoelectrical material layer 16 can be made of an inorganic and/or organic material. The inorganic substrate 14 can comprise single- or multi-layer ceramic. The piezoelectrical material layer 16 can comprise one or more of these materials: PZT, ZnO, SnO, PVDF, P(VDF-FrFE), or other equivalent materials.

In the case of deforming an illustrated piezoelectrical transducer 13, a potential difference is generated between the two electrodes 15, so as to generate electrical energy as a result.

Advantageously, the fact that the piezoelectrical transducer 13 is made of an elastic material allows the piezoelectrical transducer 13 to vibrate naturally when it is subjected to an external force. This allows the generation of the electrical energy to be prolonged over time, including upon cessation of the external force that generated the activation of the piezoelectrical transducer 13.

Another variant of the piezoelectrical transducer 13 is shown in FIG. 13. In the illustrated example, in addition to the previously described base composition, the piezoelectrical transducer 13 comprises a wafer structure that comprises, in addition to the previous description, the following sequence of components as well:
an electrode 15III;
a piezoelectrical material layer 16II;
another electrode 15IV.

The electrodes 15 are at least partially made of an electrically conductive material. The electrodes 15 can be connected to each other in series or parallel.

According to the variant shown in FIG. 14 the piezoelectrical transducer 13 can have a coating 18 made of an insulating material. The insulating material can be electrically and/or thermally and/or impermeably insulating.

Advantageously, the substrate 14 has an elastic modulus greater than 90 GPa, preferably smaller than 120 GPa.

Advantageously, the substrate 14 has a work temperature that is greater than 600° C., preferably ranging from 700° C. to 1400° C.

Therefore, a substrate 14 of this type lends itself to an application, in which the piezoelectrical transducer 13 is subjected to elevated and frequent vibrations. Furthermore, the value of the density greater than 5 g/cm³, in particular greater than 6 g/cm³, preferably greater than 8 g/cm³, allows wider oscillations to be obtained and, consequently, a greater deformation of the piezoelectrical material layer 16 in use.

When an external force causes the deformation, in particular the vibration, of the piezoelectrical material layer 16 of a piezoelectrical transducer 13 of the type described above, a difference in voltage is generated, in a known manner, between the electrodes 15.

Advantageously, according to the present invention, the energy harvesting system 10 also comprises an anchoring system 19 for being fixed, in use, to the fastener 1.

According to the example shown in FIG. 1, the anchoring system 19 is a base that is fixed (for example, by gluing or welding) in the housing 5 of the head 3.

The sensitive element 11 is substantially plate-shaped with a length 1, width w (shown in FIG. 2) and thickness t (FIG. 1). The sensitive element 11 is fixed to the anchoring system 19 in a cantilever fashion, so as to be able to move, in particular oscillate, in use, with respect to the body of the fastener 1. According to the illustrated example, the sensitive element 11 has a basically squared plan shape. The sensitive element 11 is connected to the anchoring system 19 along one side.

According to the example shown in FIGS. 1 and 2, the anchoring system 19 is configured to keep the sensitive element 11 raised in a cantilever fashion inside the housing 5 of the screw, so that during the vibrations the sensitive element 11 doesn't knock against the fastener 1. Advantageously, the mass M is fixed to the sensitive element 11 along the side opposite the one for connecting to the anchoring system 19.

The schematic form of a first embodiment of the harvesting system 10, according to the present invention, is shown in FIG. 4.

The shape and size of the mass M are a function of the type of application of the fastener 1 and they are configured so as to obtain the greatest number of vibrations possible and with the greatest breadth possible during normal use of the fastener 1.

Advantageously, the mass M has a density, which is greater than 5 g/cm³ in particular greater than 6 g/cm³, preferably greater than 8 g/cm³.

According to a variant, which is not shown, the energy harvesting system 10 can comprise a different number of masses M, for example, it can have two masses M applied in different positions to the sensitive element 11.

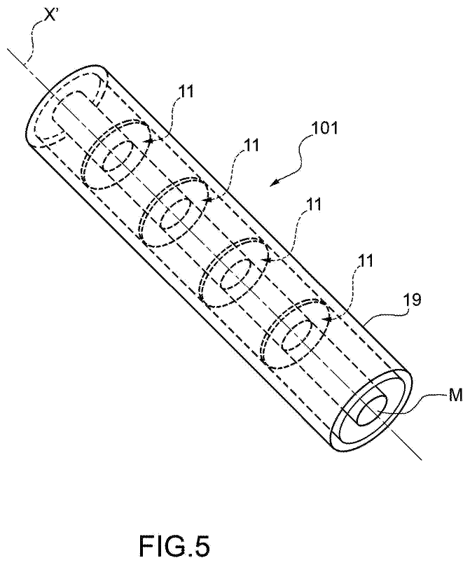

In the variant shown in FIG. 3, the harvesting system is inserted inside the shank 2 of the fastener 1. Different possible variants of the harvesting system 10, according to the present invention, are shown in FIGS. 5 to 11.

A variation of the harvesting system 10 is indicated in FIG. 5 with 101, wherein the anchoring system 19 is a tubular body, in particular with a circular section with a longitudinal axis X′, and it has an inner sliding channel 20. Furthermore, the mass M has a substantially cylindrical shape and is inserted inside the anchoring system 19. In particular, the mass M is cylindrical shaped and substantially coaxial to the longitudinal axis X′. The anchoring system 19 comprises a plurality of sensitive elements 11, each of which has a disc shape and is fitted around the mass M.

Advantageously, the sensitive elements 11 are configured so that, in use, the mass M can slide longitudinally inside the anchoring system 19. Advantageously, the sensitive elements 11 can be fixed either to the anchoring system 19 or to the mass M. If necessary, some sensitive elements 11 are fixed to the mass M, while other flexible elements 11 are fixed to the anchoring system 19.

Advantageously, in use, the mass M moves inside the anchoring system 19, causing the deformation of the sensitive elements 11.

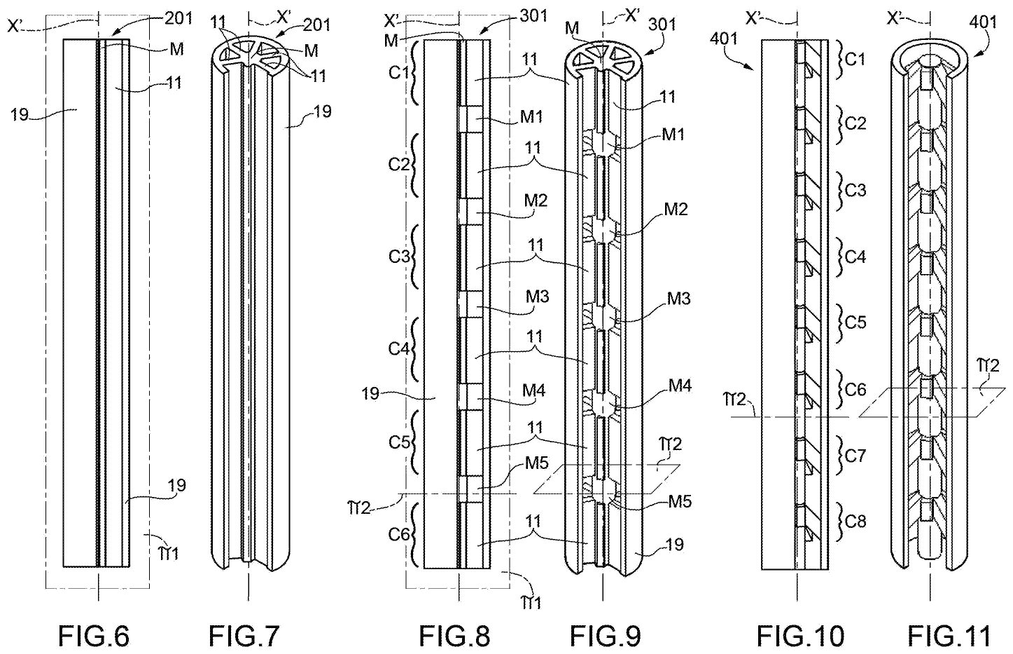

A variant of the harvesting system 10 is illustrated in FIGS. 6 and 7 with 201. According to the solution illustrated in FIGS. 6 and 7, the anchoring system 19 is formed from a tubular body with a circular section with a longitudinal axis X′ and it has an inner sliding channel 20. Furthermore, the mass M has a substantially cylindrical shape, it is inserted inside the anchoring system 19, and it is substantially coaxial to the longitudinal axis X′. The anchoring system 19 comprises a plurality of sensitive elements 11, each sensitive element 11 has the shape of a plate, projecting radially from the mass M.

The set of all of the sensitive elements 11 substantially forms a radial structure, interposed between the mass M and the anchoring system 19. Advantageously, the sensitive elements 11 are connected to the mass M or to the anchoring system 19. According to the illustrated example, the sensitive elements 11 have a longitudinal extension, which is substantially equal to the longitudinal extension of the anchoring system 19.

A variant of the harvesting system 10, according to the present invention, is illustrated in FIGS. 8 and 9 with 301.

The solution illustrated in FIGS. 8 and 9 is similar to the solution described in FIGS. 6 and 7 and differs from the latter in that it involves a plurality of sensitive elements 11 with a smaller extension than the longitudinal extension of the anchoring system 19.

Therefore, advantageously, the radial distribution of the sensitive elements 11 around the mass M is axially spaced apart. In particular, according to what is illustrated in FIGS. 8 and 9, the harvesting system 10 comprises a plurality of rings C of sensitive elements 11, each ring C is axially spaced apart from an adjacent ring C by a mass M. Advantageously, according to this technical solution, depending on the type of application of the fastener 1, it is possible to vary the entity of the mass M, so as to obtain the best resonance of the harvesting system 10, in response to the external agents.

An additional variant of the harvesting system 10, according to the present invention, is shown in FIGS. 10 and 11 with 401. Unlike the solution described in FIGS. 9 and 10, each sensitive element 11 is inclined with respect to a plane n2 perpendicular to the longitudinal axis X′ of the anchoring system 19. In this case, too, the rings C of adjacent sensitive elements are spaced apart from one another by a mass M.

Advantageously, energy harvesting systems 101, 201, 301, 401 of the type described above are inserted inside the cavity in the shank 2 of the screw so as to be substantially coaxial to the longitudinal axis X of the shank 2. The material with which it is made and/or the dimensions of the anchoring system 19 allow an interference coupling to be created inside the cavity 6 of the fastener 1. Alternatively, the anchoring system 19 is fixed inside the cavity 6 by means of intermediate bodies, for example, by means of gluing or locking elements (not shown).

Advantageously, the fact that the anchoring system 19 has a tubular body, in particular with a circular section, facilitates operations of insertion and assembly of energy harvesting systems inside the cavity 6 of the fastener 1. Advantageously, the presence of the tubular anchoring system 19 allows the energy harvesting system 10 to be positioned with a certain inclination with respect to the longitudinal axis X of the fastener 1. According to the illustrated examples, the harvesting systems 101, 201, 301, 401 are coaxial to the longitudinal axis X of the fastener 1. Therefore, it is possible to predetermine the extension and orientation of the vibrations of the masses.

According to a variant, which is not shown, the body of the fastener 1, i.e. according to the illustrated example the body of the screw directly forms the anchoring system 19 of the harvesting system 10. In this case, inside the body of the fastener 1 housings and/or cavities are present, capable of interfering and retaining the sensitive elements 11 or the mass M of the harvesting system 10.

In use, a harvesting system 10, 101, 201, 301, 401 of the type described above is installed on a fastener 1, for example, a screw. For example, it is inserted inside a housing 5 in the head 3 of the screw or inside a cavity in the shank 2 of the screw.

Thus, the harvesting system 10, 101, 201, 301, 401 can be connected to an electric circuit inside the fastener 1 (not shown). For example, the fastener 1 can be provided with sensors and the harvesting system 10 is connected to the sensors so as to supply them with electrical energy. Additionally, or alternatively, the fastener 1 can be provided with a storage unit (not shown) for storing the electrical energy produced.

Advantageously, the harvesting system 10, 101, 201, 301, 401 of the type described above can be miniaturised and inserted inside mechanical components that have limited dimensions, such as the fasteners 1, in particular the screws.

Advantageously, the fact of comprising an energy harvesting system 10, 101, 201, 301, 401 inside known fasteners 1 such as screws, allows energy harvesting systems 10, 101, 201, 301, 401 to be installed inside pre-existing complex mechanical apparatuses, exploiting the existing housings for traditional fasteners. This allows energy to be implemented and recovered from the vibrations of existing mechanical apparatuses without their having to be redesigned, ensuring the same (improved) functionality thereof.

Advantageously, it is possible to provide a plurality of fasteners on board the same mechanical apparatus, each of which is provided with a respective energy harvesting system. Thus, on board existing mechanical apparatus, it is also possible to provide a plurality of different areas for the local recovery of kinetic energy and the conversion thereof into electrical energy. In a known manner, the fasteners 1 of the same mechanical apparatus can be connected to an external electric circuit or to one or more storage units (batteries).

1. An energy harvesting system comprising:
one or more sensitive elements comprising at least one layer made of a piezoelectrical material;
a mass;
an anchoring system, which is configured to cooperate, in use, with said mass so as to at least partially deform said sensitive element;
wherein each sensitive element comprises:
a substrate;
a first electrode;
a piezoelectrical material layer;
a second electrode;
wherein the substrate is at least partially made of a material having an elastic modulus greater than 90 GPa.

2. The energy harvesting system according to claim 1, wherein the mass is connected to the sensitive element.

3. The energy harvesting system according to claim 1, wherein said anchoring system is a tubular body having a longitudinal axis and an inner sliding channel; wherein said mass is mounted so as to move inside said inner sliding channel; and comprising a plurality of sensitive elements interposed between said mass and the anchoring system so as to be deformed, in use, by relative movement between said mass and said anchoring system.

4. The energy harvesting system according to claim 3, wherein each of said plurality of sensitive elements is a disc, which is fitted around said mass.

5. The energy harvesting system according to claim 3, wherein each of said plurality of sensitive elements is a plate, which is substantially parallel to a plane, which is perpendicular to the longitudinal axis of the anchoring system (19); wherein each of said plurality of sensitive elements radially projects outwards from the mass.

6. The energy harvesting system according to claim 3, wherein each of said plurality of sensitive elements is a plate, which is radial to the mass and substantially parallel to a plane, which includes the longitudinal axis of the anchoring system; wherein said mass and each plate have a longitudinal extension, which is substantially equal to the longitudinal extension of said anchoring system.

7. The energy harvesting system according to claim 3, wherein each of said plurality of sensitive elements is a plate, which is radial to the mass and substantially parallel to a plane, which includes said longitudinal axis; wherein said mass and each plate have a longitudinal extension, which is smaller than the one of the anchoring system; . and further comprising a plurality of rings of sensitive elements arranged radially relative to the mass; wherein between two adjacent rings there is interposed a further mass, whose extent is a function of a predefined resonance frequency.

8. The energy harvesting system according to claim 6, wherein each of said plurality of sensitive elements is a plate, which is inclined relative to a plane, which is perpendicular to the longitudinal axis.

9. The energy harvesting system according to claims 3, wherein the extent of the mass along said longitudinal axis is variable depending on a predefined resonance frequency.

10. The energy harvesting system according to claim 1, wherein the mass has a density, which is greater than 5 g/cm³.

11. The energy harvesting system according to claim 1, wherein the substrate has a work temperature that is greater than 600° C.

12. A fastener, comprising an energy harvesting system according to claim 1.

13. The fastener according to claim 12, further comprising a shank having a longitudinal axis and an inner cavity; wherein said energy harvesting system is inserted inside said inner cavity; wherein the body of the fastener makes up said anchoring system of the energy harvesting system or said anchoring system is fixed inside the cavity of the fastener.

14. A use of an energy harvesting system according to claims 1 in a fastener.

15. A method for the conversion of kinetic energy into electrical energy by means of an energy harvesting system according to claims 1, the method comprising the steps of: installing an energy harvesting system according to claims 1 in a fastener; installing said fastener on a mechanical apparatus; converting the kinetic energy, including vibrations, of said mechanical apparatus into electrical energy at said fastener by means of said energy harvesting system.

16. The method according to claim 15, further comprising the step of installing a plurality of harvesting systems each one inside a respective fastener and installing each fastener on a mechanical apparatus in respective different areas; converting the kinetic energy, including vibrations, of said mechanical apparatus into electrical energy at each fastener by means of a respective energy harvesting system; storing and/or reusing the kinetic energy produced by each fastener in a storage unit or in an electric circuit.

17. The energy harvesting system according to claim 1, wherein the substrate is at least partially made of a material having an elastic modulus less than 120 GPa.

18. The energy harvesting system according to claim 1, wherein the mass has a density which is greater than 6 g/cm³.

19. The energy harvesting system according to claim 1, wherein the mass has a density which is greater than 8 g/cm³.

20. The energy harvesting system according to claim 1, wherein the substrate has a work temperature that ranges from 700° C. to 1400° C.
